(19) United States
(12) Patent Application Publication
(10) Pub. No.: US 2026/0090398 A1
(43) Pub. Date: Mar. 26, 2026

(54) REPAIR OF SIGNAL PATHS FOR STACKED DIE

(71) Applicant: Intel Corporation, Santa Clara, CA (US)

(72) Inventors: Rakesh Kandula, Bangalore (IN); Sriram Venkatesan, Fremont, CA (US); Jeffrey Soriano, El Dorado Hills, CA (US); Takeshi Nakazawa, Phoenix, AZ (US)

(21) Appl. No.: 18/898,059

(22) Filed: Sep. 26, 2024

(51) Int. Cl. H01L 21/48; G01R 31/26; H01L 23/00; H01L 23/48; H01L 23/538; H01L 25/065

(52) U.S. Cl. CPC H10W 70/092; G01R 31/2642; G01R 31/2644; H10W 20/20; H10W 70/611; H10W 70/635; H10W 90/00; H10W 90/722; H10W 90/724

(57) ABSTRACT

Embodiments herein relate to ensuring the integrity of signal paths in stacked semiconductor devices. In an example implementation, a faulty signal path between die can be repaired by re-routing the path within the affected die, in a per-layer repair approach. Also disclosed are a sequential repair process for N-stacked die prior to integration, an in-field fault detection and repair technique, a proactive in-field repair technique for preemptive die maintenance, and a technique to drive select lines of repair multiplexers to provide rerouting of signal paths.

### BACKGROUND

Die stacking in a semiconductor device involves stacking multiple die on top of one another to provide a smaller form factor. In some cases, the die are chiplets, which can have different functions and may be fabricated using different technologies. Conductive paths extend through and between the dies to provide the required signals and voltages. For example, through-silicon vias within a die and interconnects between adjacent die can be used. However, various challenges are presented in ensuring the integrity of the signal paths.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A depicts an example semiconductor device 100 having stacked die, in accordance with various embodiments.

FIG. 1B depicts an example transmission of a test pattern signal in the stack 130 of FIG. 1A, in accordance with various embodiments.

FIG. 2 depicts a pair of adjacent die 200 which can detect and repair a faulty interconnect between the two die, in accordance with various embodiments.

FIG. 3 depicts a stack of die 300 where the top and bottom die, but not the intermediate die, can detect and repair a faulty interconnect between the top and bottom die, in accordance with various embodiments.

FIG. 4A depicts a first transmit die, Die1, and a second transmit/receive die, Die2, in a top portion 400A of a stack, in accordance with various embodiments.

FIG. 4B depicts a third transmit/receive die, Die3, and a fourth receive die, Die4, in a bottom portion 400B of the stack of FIG. 4A, in accordance with various embodiments.

FIG. 5 depicts an in-field repair solution for preemptive chiplet maintenance, in accordance with various embodiments.

FIG. 6 depicts a stack of die 600 having a multiplexer (mux) select fuse bus 610 coupled to receive and forward repair multiplexers (muxes), in accordance with various embodiments.

FIG. 7 depicts a table of example descriptions for the multiplexer select fuse bus 610 of FIG. 6, in accordance with various embodiments.

FIG. 8 depicts a stack of die 800 having the multiplexer select fuse bus 610 of FIG. 6 and fuse decoders coupled to receive and forward repair multiplexers, in accordance with various embodiments.

FIG. 9 depicts a bar graph of percentage of yield loss versus a number of chiplets in a stack, analyzed based on the quantity of repair lanes and the repair strategy, in accordance with various embodiments.

FIG. 10 illustrates an example of components that may be present in a computing system 1050 for implementing the techniques (e.g., operations, processes, methods, and methodologies) described herein.

### DETAILED DESCRIPTION

As mentioned at the outset, various challenges are encountered in ensuring the integrity of signal paths in stacked semiconductor devices.

In particular, as heterogenous die integration is becoming more common place to support large compute and memory capacity, product architectures are moving to three-dimensional (3D) integrated circuit (IC) designs. As a result, test and assembly challenges are increasing. With a product architecture having a number N of stacked die, for example, the cost of discarding the assembled units due to assembly defects is prohibitive. An effective and robust repair mechanism would be desirable to meet the yield and cost requirements of the product.

The solutions provided herein address the above and other issues In one aspect, an architecture is provided that detects and repairs faulty signal paths in a stack of die, to optimize yield and cost. The solutions allow detection and repair in the manufacturing and testing environment as well as in the field. For example, in data centers and automotive applications, it is desirable to repair stacked components in the field while the semiconductor device is in use. The solutions can be used to execute repairs on-site without disrupting ongoing traffic, ensuring continuous operation and reliability.

In an example implementation, a faulty signal path between die can be repaired by using multiplexers to re-route the path within the affected die, in a per-layer repair approach. In another aspect, a faulty signal path between die can be repaired by re-routing the path within the entire stack, in a full-stack repair approach.

The solutions can include a number of features, including an N-stacked die repair architecture, a sequential repair process for N-stacked die prior to integration, an in-field fault detection and repair technique, a proactive in-field repair technique for preemptive die maintenance, and a technique to drive select lines of repair multiplexers to provide rerouting of signal paths.

The solutions provide a number of advantages. First, the N-stacked die repair architecture enhances the reliability and longevity of multi-layered chip systems, allows for scalability in design, accommodating an increasing number of stacked die, and facilitates complex repairs that are not possible with simpler, two-stack architectures. Second, the sequential repair process for N-stacked die prior to integration ensures that each die layer is fully functional before it is integrated with others, reducing the risk of systemic failures, streamlines the manufacturing process by identifying and addressing defects early on, and improves overall yield and reduces cost by preventing the assembly of defective stacks. Third, the in-field fault detection and repair technique for N-stacked die minimizes downtime by allowing repairs without the need to remove the chip from its operational environment, increases the service life of devices by ensuring that faults can be corrected as they arise, and reduces maintenance costs by avoiding complete system overhauls for isolated issues. Fourth, the proactive in-field repair technique for preemptive die maintenance predicts potential failures before they occur, ensuring uninterrupted service, utilizes advanced analytics and diagnostics to maintain optimal chip performance, and enhances customer trust by providing a robust and self-maintaining hardware solution. Fifth, the technique to drive select lines of repair multiplexers provides rerouting of signal paths.

These and other features will be further apparent in view of the following discussion.

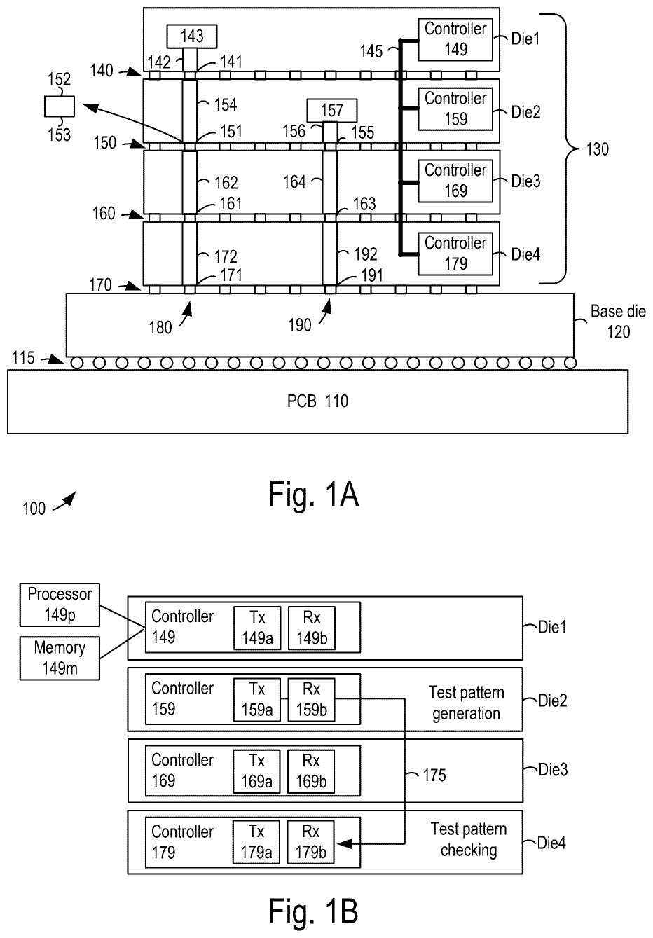

FIG. 1A depicts an example semiconductor device 100 having stacked die, in accordance with various embodiments. The device includes a base die 120 attached to a printed circuit board (PCB) 110 via interconnects 115 such as micro-bumps, copper hybrid bonding which uses, e.g., tiny copper-to-copper connections, or bump less hybrid bonding which uses a dielectric bond and embedded metal to form interconnections. A stack of die 130 such as chiplets is attached to the base die in this example. The stack includes four die, Die1, Die2, Die3 and Die4, although the techniques are scalable to include, e.g., up to 8 or 16 die. The stacked die are attached to one another by interconnects. For example, Die1 and Die2 are attached by interconnects 140, Die2 and Die3 are attached by interconnects 150, and Die3 and Die4 are attached by interconnects 160. Additionally, Die4 is attached to the base die by interconnects 170.

The interconnects provide conductive paths between the die and may extend along the two-dimensional (2D) top and bottom surfaces of the die in rows and columns. An example interconnect 151 between Die2 and Die3 is depicted. A top surface of the interconnect 151 is a contact 152 of Die 2, and a bottom surface of the interconnect 151 is a contact 153 of Die 3. The contacts are referred to as pads or bond pads in some cases. Each die thus has a number of contacts on its top and bottom surfaces which are electrically coupled to contacts on adjacent die. Additionally, vias such as through-silicon vias (TSV) can extend in the dies to form conductive paths between the top and bottom contacts/interconnects of a die. For example, a TSV 172 extends between interconnects 161 and 171, a TSV 162 extends between interconnects 151 and 161, a TSV 154 extends between interconnects 141 and 151. Additionally, a TSV 142 extends from the interconnect 141 to a circuit 143 in Die1. A conductive path 180, e.g., a signal path, is thus formed from the base die through the stack to the top die, Die1, by these interconnects and TSVs.

In some cases, a signal path extends only partway up in the stack. For example, a conductive path 190 includes an interconnect 191, a TSV 192, an interconnect 163, a TSV 164, an interconnect 155, and a TSV 156 coupled to a circuit 157 in Die2. Generally, many different signal paths are provided through the respective interconnects and contacts of the die.

Die2, Die3 and Die4 can each include interconnects on a top, first side of the die and on an opposing bottom, second side of the die. The topmost die, Die1, can include interconnects on a bottom side of the die.

Each die can further include a controller, e.g., control circuit, which is configured to detect and repair faults in the signal paths. For example, Die1, Die2, Die3 and Die4 include controllers 149, 159, 169 and 179, respectively, which communicate with each other via a bus 145 or other communication paths. The controller can include a memory which stores instructions for execution by a processor to perform the repair techniques described herein. In one approach, the repair techniques are performed by the controllers without guidance from an external control circuit, e.g., external to the stack 130. This is an advantage as it allows for in-field repairs. In another possible approach, the controllers can communicate with an external circuit such as to receive commands and/or to report data regarding a status of the signal paths. The status can indicate, e.g., specific repairs which were made including an identity of the signal paths involved, and/or a report of a health of the signal paths based on evaluations made by sensors on the die.

The die can include any type of circuits. In one approach, one or more of the die contain high-bandwidth memory such as dynamic random-access memory (DRAM) for use in applications such as artificial intelligence (AI).

FIG. 1B depicts an example transmission of a test pattern signal in the stack 130 of FIG. 1A, in accordance with various embodiments. The repair architecture can involve two types of N-dimensional integrated circuit (IC) Built-in self-test (BIST) controllers, namely a transmit controller and a receive controller. For example, the controllers 149, 159, 169 and 179 can include a transmit (Tx) controller 149a, 159a, 169a and 179a, respectively, and a receive (Rx) controller 149b, 159b, 169b and 179b, respectively. For simplicity, a single controller is sometimes shown which can have both transmit and receive capabilities.

The controllers may each include a memory to store instructions such as firmware and a processor to execute the instructions to provide the features discussed herein. For example, the controller 149 includes a processor 149p and a memory 149m.

In this example, the transmit controller 159a of Die2 generates a test pattern signal and transmits it on a signal path 175 to the receive controller 179b of Die4, where the test pattern is checked to evaluate the signal path 175. Many other variations are possible.

Generally, there is a higher risk of defects for higher die in the stack, based on factors such as the use of ever-smaller pitch between micro-bumps or other contacts. Accordingly, the capability of the stack should be tested per die attach.

By providing controllers within the stack for detecting and repairing a faulty signal path, the repairs can be made without affecting the base die. The base die does not have to modify its assignment of contacts. Thus, a certain contact which is assigned to a respective signal path on the base die can continue to be used.

This is in contrast to repair solutions which involve using redundancies of every die in the stack regardless of the defect location, such that defects on any of the stacked die would have to be repaired on the base die, and every repair solution on the base die has to be replicated on each stacked die for proper signal propagation post-repair.

As mentioned at the outset, the fault detection and repair techniques can include a number of aspects. A first aspect is an N-stacked die repair architecture. This can include a full stack repair, or a repair or redundancy at each layer/die, e.g., a per-layer repair. As mentioned, full-stack repair can involve repairing a faulty signal path between die by re-routing the path within the entire stack, in each die of the stack. A per-layer repair can involve limiting the re-routing of a faulty path to within the affected die.

A second aspect is a sequential testing and repair process for N-stacked die prior to pairing of subsequent die. A third aspect is in-field fault detection and repair for N-stacked die. A fourth aspect is proactive in-field repair for preemptive die maintenance. A fifth aspect is a technique to drive the select lines of repair multiplexers.

In FIG. 1B, the transmit controller 159a is used in Die2 and the receive controller 179b is used in Die4. In one approach, the transmit controller 159a can be accessed externally such as via the IEEE 1838: Test Access Architecture for 3D Stacked IC or the IEEE 1149.1 JTAG protocols (Institute of Electrical and Electronics Engineers; Joint Test Action Group). IEEE 1838 provides a modular test access architecture, in which dies and interconnect layers between adjacent stacked dies can be tested individually. JTAG is an integrated method for testing interconnects on printed circuit boards (PCBs) that are implemented at the integrated circuit (IC) level. The transmit controller 159a can contain registers such as test_start, the number of clock cycles for testing, and a LFSR (linear-feedback shift register) seed, among others.

Similarly, the receive controller 179b, also accessible through the same protocols, can hold registers for test_start, MISR (multiple-input signature register) seed, identification of failing lanes/signal paths, test_pass, test_done, and more.

The transmit controller 159a can generate various test patterns, which may include customized patterns for double data rate scenarios, toggle patterns, or pseudo-random patterns, and those produced by an LFSR.

Conversely, the receive controller 179b verifies the incoming test patterns. If the received pattern differs from the expected pattern, it logs the failing lane (signal path) number in an associated register. If the patterns align, all registers remain at all 1's, which indicates no failures and an invalid value.

In the end, a user can read the status registers test_pass and test_done. Both registers are set to 1 if the received patterns correspond to the expected patterns. If there is a mismatch, test_pass is set to 0, and test_done is set to 1, indicating the completion of the test without a pass. The receiver controller 179b also logs in the failing lane numbers.

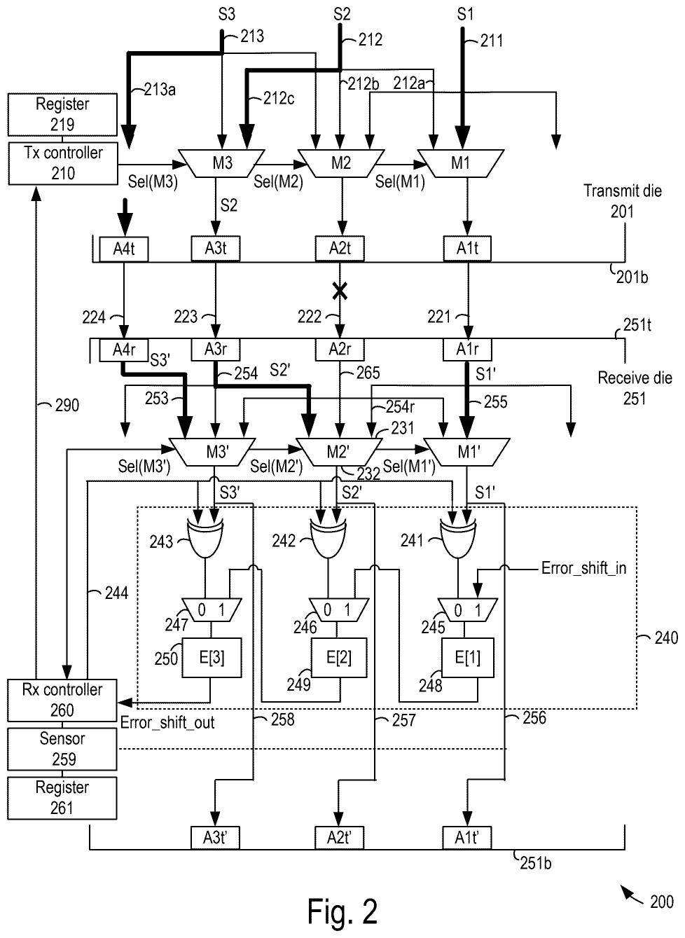

FIG. 2 depicts a pair of adjacent die 200 which can detect and repair a faulty interconnect between the two die, in accordance with various embodiments. To detect a fault in a signal path between two die, one die can act as a transmit die 201 which transmits a test signal to a receive die 251 on a signal path. For example, the transmit and receive die can be Die1 and Die2, respectively, Die2 and Die3, respectively, or Die3 and Die4, respectively, of FIG. 2.

The receive die can compare a detected signal on the signal path to a comparison signal/expected signal which is the same as the test pattern, to determine whether there is a discrepancy, indicating a fault in the signal path. The receive die 251 can report back to the transmit die with a result of the test, including an identification of whether the signal path was found to be faulty and an identification of a signal path used as a repair or alternative to the faulty path. The fault detection and repair process can be carried out by a transmit controller 210 and a receive controller 260 of the die 201 and 251, respectively. The controllers are also referred to as control circuits.

The process can be initiated by the transmit die at various times. In one approach, the process is initiated during the manufacturing/test progress by an external controller which communicates with the stack of die. In another approach, the process is initiated by the transmit die 201 based on various monitored criteria such as periodically, based on an amount of usage/operations performed on the die, or based on a detection of errors or slower than normal performance in circuits on the transmit die 201.

The transmit die 201 includes example first, second and third contacts A1t, A2t and A3t, respectively, at the bottom 201b of the die 201. The contacts can be adjacent to one another, for example. The contacts A1t, A2t and A3t, are coupled to the outputs of multiplexers M1, M2 and M3, respectively, which are controlled by signals on select lines Sel(M1), Sel(M2) and Sel(M3), respectively, by the transmit controller 210. Each multiplexer (mux) is coupled at its input side to signal paths for first, second and third signals, S1, S2 and S3, respectively. During a test, the signal can be test pattern signals, such as generated by the transmit controller 210. At other times, the signals can be from circuits and/or vias in the transmit die 201. In one approach, one test signal at a time is used.

This example allows repair of a faulty path with one of two adjacent paths using a 3:1 mux. Other approaches are possible. Generally, a repair of a faulty signal path can be made with one of X≥1 alternative signal paths using a (X+1):1 mux.

The signal paths 211, 212 and 213 for S1, S2 and S3, respectively, are split into three paths, one for each of the multiplexers. For example, the signal path 212 is split into signal paths 212a, 212b and 212c which are coupled to M1, M2 and M3, respectively. Initially, when the transmit controller 210 is not aware of any fault with the interconnects 221, 222 and 223 between the die, the transmit controller 210 selects the central path of the three paths for each signal at the multiplexers as a default, and these central paths are coupled to A1t, A2t and A3t, and then to the contacts A1r, A2r and A3r, respectively, via the interconnects 221, 222 and 223, respectively.

The transmit controller 210 is coupled to a register 219 which stores information on how to route the signals through the muxes M1, M2 and M3. The transmit controller sets the signals on select lines Sel(M1), Sel(M2) and Sel(M3) based on the data in the register. This data is received from the receive controller 260 in response to its testing of the signal paths. Initially, the register data informs the transmit controller to pass the central signal of the three signals received at each mux. When a fault is detected, the register data informs the transmit controller to re-route one of the signals so that it passes through a different mux via its left or right branch. For example, S2 passes through M3 instead of M2 via the left branch 212c. S3 is routed on a path 213a to a multiplexer which is not shown. This multiplexer outputs S3 via A4t.

At the receive die, before a fault is detected, the receive controller 260 sets the select signals Sel(M1′), Sel(M2′) and Sel(M3′), to cause the multiplexers M1′, M2′ and M3′ to pass the central signal at their input sides to their respective outputs as signals S1′, S2′ and S3′. For example, M2′ has an input side 231 and an output 232. The signals S1′, S2′ and S3′ can then be evaluated at a logic circuit 240 to determine whether they are faulty. The logic circuit can include exclusive-OR (XOR) gates 241, 242 and 243 (e.g., examples of logic gates) which compare S1′, S2′ and S3′ to respective comparison signals from the receive controller 260 on paths 244. The comparison can be an a per-bit basis. S1′, S2′ and S3′ are digital signals, in this example. The receive controller 260 can set the timing of the comparison signals based on a synchronization signal received from the transmit controller 210 during the test. The output of each XOR gate is a 0 if both input bits are the same, or a 1 if the input bits differ, indicating a fault in the signal path. A fault can represent various situations such as an open circuit, short circuit, or a highly resistive path. The faults can be present at the time of manufacture or develop when the device is in the field.

The output bits of the XOR gates 241, 242 and 243 are provided to multiplexers 245, 246 and 247, respectively. The mux 245 is triggered by an Error_shift_in signal to pass a bit from 241 XOR to a flip-flop circuit E[1] 248. The output of E[1] is provided as an input to the mux 246 to pass a bit from XOR 242 to a flip-flop circuit E[2] 249. The output of E[2] is provided as an input to the mux 247 to pass a bit from XOR 243 to a flip-flop circuit E[3] 250. The output of E[3] is then provided to the receive controller 260 as Error_shift_out. Error_shift_out can include the bits from the XOR gates which indicate whether the associated signal is faulty.

When the receive controller 260 determines from the logic circuit 240 that a signal path is faulty, it reports the result to the transmit controller 210 on a signal path 290 in a message. In this example, assume the interconnect 222 is faulty, as denoted by an “X.” When the transmit controller 210 learns from the receive controller 260 that there is a fault with the interconnect 222, the transmit controller 210 re-routes S2, the signal which corresponds to the faulty interconnect A2t, to M3. In this case, no signal path is selected at M2, and the central signal path continues to be selected at M1. Additionally, S3, which would normally be routed to A3t via M3, is instead routed to another multiplexer, not shown, to a contact A4t of the transmit die 201, which in turn is connected to a contact A4r of the receive die 251. The heavy lines denotes the active signal paths in the case of this example fault.

At the receive die 251, the controller sets the select signals Sel(M1′), Sel(M2′) and Sel(M3′) to route S3′ from A4r and on a path 253 to M3′, and to route S2′ from A3r and on a path 254 to M2′. S1′ continues to be routed from A1r on a path 255 to M1′. S1′, S2′ and S3′ are the versions of the signal paths in the receive die 251 corresponding to S1, S2 and S3, respectively, in the transmit die 201. The paths 212c and 254 form an alternative signal path for S2.

Additionally, the outputs S1′, S2′ and S3′ are routed from the respective multiplexers to output paths 256, 257 and 258 for use by circuits in the receive die 251 and/or to be forwarded on to the next die in the stack after the receive die. The output paths 256, 257 and 258 can comprise TSVs, for example. When the output signals S1′, S2′ and S3′ are forwarded on to the next die, they can be routed to contacts A1t′, A2t′ and A3t′, respectively, which correspond to the contacts A1r, A2r and A3r, respectively.

In an example implementation, A1r, A2r, A3r are first, second and third contacts at a first side 251t of the receive die 251, and A1t′, A2t′, A3t′ are first, second and third contacts in respective signal paths 256, 257 and 258 with the first, second and third contacts at the first side of the die, at a second side 251b of the die, opposite the first side. M2 is a multiplexer having an input side 231 coupled to the first, second and third contacts at the first side of the die, and an output 232 (or output side) coupled to the second contact A2t′ at the second side 251b of the receive die 251.

During a test, before a fault is detected, the input side 231 of M2′ receives a test signal S2 from the second contact A2r at the first side 251t of the die, and via the path 265, and routes the test signal to the logic circuit 240 by setting Sel(M2′) to couple the input path 231 to the output path 257. The logic circuit receives a comparison signal on the path 244 from the receive controller 260, and indicates whether the test signal matches the comparison signal. When the test signal does no match the comparison signal, a fault in the interconnect 222 is detected, and the receive controller 260 stores data in the register indicating that Sel(M2′) should be set to have M2′ couple the left path 254 (in place of the center path 265) to the output path 257. The receive controller can select the left hand path 254 or the right hand path 254r as an alternative path.

The receive controller 260 can also detect a fault in a signal path or otherwise evaluate a signal path using one or more sensors, such as a sensor 259, which is coupled to the signal paths 256-258. In one approach, a separate sensor is provided for each signal path. In another approach, a separate sensor is shared among multiple signal paths, such as via one or more multiplexers. Due to the additional circuitry of the sensor, it may be used for a selected subset of all signal paths such as those which are believed to be more important in the stack or more susceptible to faults.

The sensor can be a circuit which measures, e.g., timing margin, voltage and/or voltage droop, for example. Timing margin defines the difference between the actual change in a signal and the latest time at which the signal can change in order for an electronic circuit to function correctly. For example, the transmit controller 210 on the transmit die can inform the receive controller 260 on the receive die that it is sending a signal which transitions from 0 V to a target voltage. The sensor 259 can then measure the time it takes for the signal as received to transition to the target voltage, or to some specified fraction of the target voltage. The measured time can then be compared to one or more thresholds stored in a register 261. For example, a threshold may indicate the signal should have a timing margin of at least 1 time unit. If the measured timing margin is less than 1 time unit, the sensor sets a pass/fail status of the signal to fail.

It is also possible to use different thresholds at different times in the lifetime of the memory device. For example, a smaller threshold can be used as the device ages and its performance, including its signal path performance, is expected to deteriorate, so that a pass status can be set even if the measured timing margin decreases over the lifetime of the semiconductor device. For example, a smaller timing margin threshold can be used as the die ages.

In another aspect, the sensor can report a health of a signal path based on comparisons to one or more thresholds. The health can be reported by the controller to an external computing device as a warning that the health of a signal path has deteriorated even if it has not yet triggered a fail status. The external computing device and/or an associated user can take an appropriate action such as scheduling a replacement of the stacked die semiconductor device. For example, the controller and/or sensor can send an interrupt to an external power management controller (PMC) informing it that a certain threshold condition has been met in a signal path. The PMC can be a circuit which helps to manage the amount of current supplied to various parts of a system.

The sensor can use the predictive approach to detect in-field marginality and apply a repair before the device fails, to keep the product robust.

The sensor could also include a digital temperature sensor and/or a digital aging sensor. The sensor can be used in addition to the logic circuit 240 or as an alternative, to evaluate the signal paths.

In an example implementation, the sensor 259 is coupled to the second contact A2r, and the sensor receives a signal S2′ from the second contact, performs an evaluation of the signal, and based on the evaluation, provides a pass/fail status regarding the signal to the control circuit. In the example shown, the sensor is coupled to the second contact A2r via M2′ and the path 257. In another option, the sensor is coupled to the second contact A2r directly and not via M2′.

The detect and repair process can be performed at times when the signal paths and/or dies are not being used for other purposes, e.g., when they are idle, to avoid interfering with the normal use of the stacked die.

Generally, FIG. 2 depicts a repair technique where a test input is injected from the top die to the bottom die, and on the bottom die, this input is compared against an expected pattern. If there is a mismatch, the corresponding error flop E[3], E[2], E[1] is set to 1. The receive controller 260 then shifts out the error flop chain through Error_shift_in and reads it out through Error_shift_out to identify the specific failing lane.

To facilitate this repair technique, a muxing structure is coupled to the 3D IC die contacts or pads {A1, A2, A3} and {A1′, A2′, A3′} on the top and bottom dies, respectively. These are paired with three-input repair muxes {M1, M2, M3} and {M1′, M2′, M3′}. The repair muxes {M1, M2, M3} on the input side selects one of three signals to pass through the contact. For instance, M2 can route signal S2 or its neighboring signals S3 or S1 through contact A2. Conversely, the repair muxes {M1′, M2′, M3′} on the output side choose which pad's signal to output. For example, M2′ can select the signal from contact A2′ or its neighbor contacts A1′ or A3′.

The select signals for the repair muxes (M1, M2, M3, M1′, M2′, M3′) can be defined as:
00—center signal is driven to the output,
01—left signal is driven to the output,
10—right signal is driven to the output.

For example, assuming lane 2 (representing S2) fails during the testing. Before a repair, E[2] is set to 1. S2 is rerouted left via M3 to bypass the faulty interconnect between A2 and A2′. On the output side, the signal is shifted right using M2′ to realign the circuit's original functionality, connecting signal S2 with S2′. Post-repair, since lane 2 has been repaired using lane 3's path, the receive controller 260 omits E[3] after reading out the chain. In addition, the receive controller 260 reads the chain E[1], E[2], E[3] and records the failing lane number. For example, after reading the chain, if the controller reads E[2] as 1, then that lane is failing. This information is stored inside the register 261 of the receive controller 260.

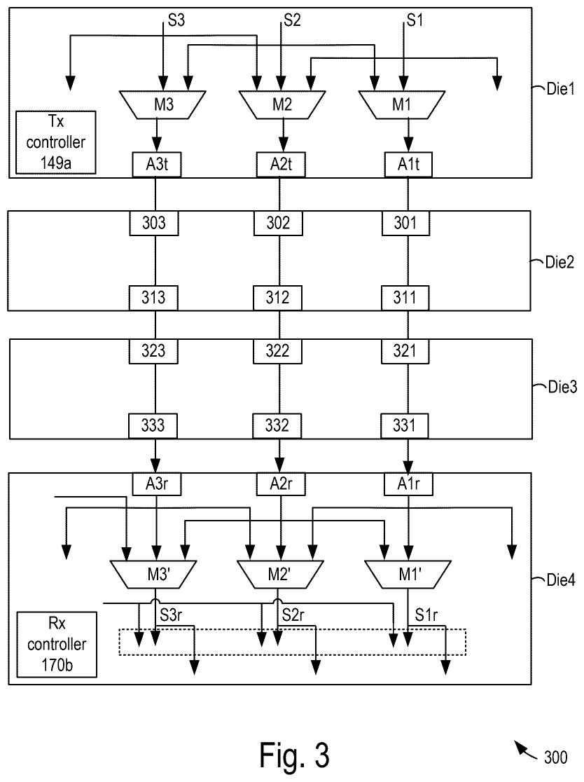

FIG. 3 depicts a stack of die 300 where the top and bottom die, but not the intermediate die, can detect and repair a faulty interconnect between the top and bottom die, in accordance with various embodiments. The stack includes Die1, Die2, Die3 and Die4, where Die1 includes the transmit controller 149a and Die4 includes the receive controller 170b, consistent with FIG. 1B. The topmost die, Die1, can correspond to the transmit die 201 of FIG. 2, and the bottommost die, Die4, can correspond to the receive die 251 of FIG. 2. The transmit and receive die omit some of the details of FIG. 2 for simplicity.

The transmit and receive die are separated by Die2 and Die3 in this example, which are assumed to not be configured to detect and repair faulty signal paths. This approach can be more economical as it is limited to detecting and repairing signal paths which extend throughout the stack.

In particular, the contact A1t of Die1 is coupled to the contact A1r of Die4 by contacts 301 and 311 in Die2 and contacts 321 and 331 in Die3. The contact A2t of Die1 is coupled to the contact A2r of Die4 by contacts 302 and 312 in Die2 and contacts 322 and 332 in Die3. The contact A3t of Die1 is coupled to the contact A3r of Die4 by contacts 303 and 313 in Die2 and contacts 323 and 333 in Die3.

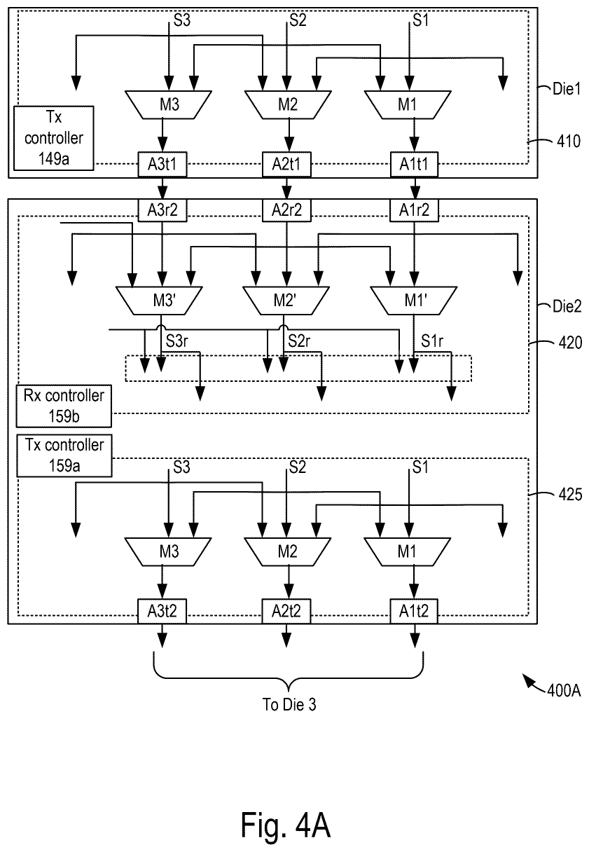

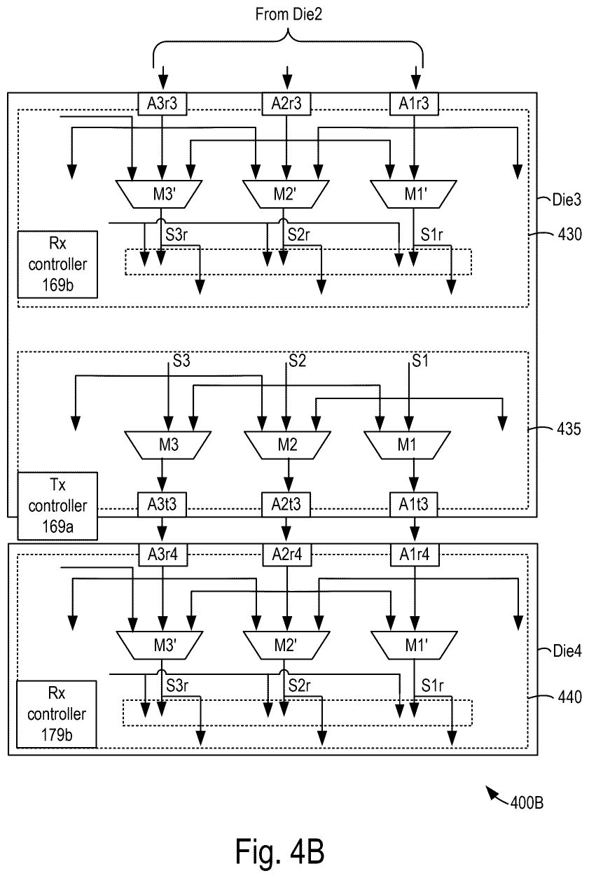

In the stack represented by FIGS. 4A and 4B, the topmost and bottommost die in the stack have a transmit and receive capability, respectively, and the intermediate die, e.g., Die2 and Die3, each have a transmit and receive capability, in accordance with various embodiments. This allows for detection and repair of signal paths through the stack.

As mentioned at the outset, a first solution involves an N-stacked die repair architecture which can include a full stack repair or a per-layer repair. As N high die are assembled, any uncorrectable defect on any die of the stack would lead to discarding the entire stack. Different repair techniques can be deployed by the product-based nature of the defects and the KPI (key performance indicator) impact to the product to repair them as a function of yield requirement.

The full stack repair approach can include replacing all the bonding across the entire stack even if there is a defect in just one die of the stack. The die which do not have a defect in that location also have their signal paths shifted to align with the shifted paths of the defective die. This is a more expensive redundancy requirement but a straightforward way to detect and fix defects.

FIG. 3 provides a configuration involving four stacked die. In this example, the first die, Die1, has redundancy muxes (M1, M2, M3), and the last die, Die4, has redundancy or repair muxes (M1′, M2′, M3′). The intermediate die, Die2 and Die3, do not feature any repair or redundancy muxes.

Note that the figures illustrate only one redundant lane for the sake of simplicity. In a realistic scenario the number of redundant lanes could be multiple based on the SoC yield requirements.

A potential disadvantage of the full stack repair technique is that, if there is a defect between Die1 and Die2, the entire route from Die1 to Die4 is replaced, in one implementation.

For example, assume lane 2 fails during testing between Die1 and Die2. Consistent with FIG. 2, S2 is rerouted down via M3 in Die1 to bypass the faulty interconnect between A2t in Die1 and A2r in Die4. On the output side in Die4, the signal through A3r is shifted using M2′ to realign the circuit's original functionality, connecting signal S2 from Die1 with S2′ in Die4. The entire connection from A2t on Die1 to A2r on Die4 is rerouted to run via A3t on Die1 to A3r on Die4. This implies that a defect between any two die (e.g., Die1 and Die2, or Die2 and Die3) affects the entire routing path, thereby limiting the ability to repair a larger number of defects.

Die1 features forwarding redundancy multiplexers, which are paired with a transmit controller, and Die4 includes receiving redundancy multiplexers that are paired with a receive controller.

FIG. 4A depicts a first transmit die, Die1, and a second transmit/receive die, Die2, in a top portion 400A of a stack, in accordance with various embodiments. Die1 includes transmit circuits 410, and Die2 includes a receive circuit 420 and a transmit circuit 425. To detect a fault in the interconnects between Die1 and Die2, the transmit circuit 410, under the control of the transmit (Tx) controller 149a, provides signals on contacts A1t1, A2t1 and A3t1 of Die1 to contacts A1r2, A2r2 and A3r2, respectively, of Die2. The receive (Rx) circuit 420, under the control of the receive controller 159b, processes the signals using a logic circuit and/or sensors, such as discussed previously. The receive controller 159b informs the transmit controller 149a of any faults and the involved signal paths to allow the transmit controller 149a to provide a re-routing of the path via the multiplexers in the transmit circuit 410. The receive controller 159b can provide a corresponding re-routing using its multiplexers in the receive circuit 420.

The transmit circuit 425, under the control of the transmit controller 159a, can be used with the receive circuit 430 of FIG. 4B to detect a fault in the interconnects between Die2 and Die3.

FIG. 4B depicts a third transmit/receive die, Die3, and a fourth receive die, Die4, in a bottom portion 400B of the stack of FIG. 4A, in accordance with various embodiments. To detect a fault in the interconnects between Die2 and Die3, the transmit circuit 425 routes test signals S1, S2 and S3 on contacts A1t2, A2t2 and A3t2 to corresponding contacts A1r3, A2r3 and A3r3, respectively, in Die3. The receive circuit 430 processes the signals using a logic circuit and/or sensors. The receive controller 169b informs the transmit controller 159a of any faults and the involved signal paths to allow the transmit controller 159a to provide a re-routing of the path via the multiplexers in the transmit circuit 425. The receive controller 169b can provide a corresponding re-routing using its multiplexers in the receive circuit 430.

To detect a fault in the interconnects between Die3 and Die4, the transmit circuit 435 provides signals on contacts A1t3, A2t3 and A3t3 of Die3 to contacts A1r4, A2r4 and A3r4, respectively, of Die4, and the receive circuit 440 processes the signals using a logic circuit and/or sensors. The receive controller 179b informs the controller 169 of any faults and the involved signal paths to allow the controller 169 to provide a re-routing of the path via the multiplexers in the transmit circuit 435. The receive controller 179b can provide a corresponding re-routing using its multiplexers in the receive circuit 440.

Note that in the above examples, the transmit direction of a test signal is from a higher die to a lower die in the stack. However, the reverse case is possible as well, from a lower die to a higher die.

The per-layer repair can be a more elegant way to fix the defects. It involves detecting defects between every two adjacent die and shifting paths within them. In this approach, circuitry is provided to keep track of the layer defect information and optimally re-route paths. Compared to the full stack repair, this approach requires less redundancy but has additional design complexity.

In particular, with full stack repair, redundancy muxes are not required at every layer/die. With the per-layer repair, redundancy muxes are located in each die. For instance, Die1 has transmit redundancy muxes. Die2 has receive muxes which connect to Die1, and transmit muxes which connect to Die3, and Die3 has receive muxes which connect to Die2, and transmit muxes which connect to Die4. Finally, Die4 contains receive redundancy muxes, which interface with Die3. This layered redundancy ensures that each die can independently address and repair faults, enhancing the overall reliability of the chip stack.

FIG. 4A shows that Die1 has forwarding redundancy multiplexers which are paired with the transmit controller 149a. Similarly, Die2 includes receiving redundancy multiplexers that are paired with the receive controller 159b. Moreover, since Die2 is also interfacing with Die3, Die2 features forwarding redundancy multiplexers, which are paired with the transmit controller 159a.

In FIG. 4B, Die3 includes receiving redundancy multiplexers that are paired with the receive controller 169b, and forwarding redundancy multiplexers, which are paired with the transmit controller 169a. Die4 includes receiving redundancy multiplexers that are paired with the receive controller 179b.

As mentioned at the outset, a second solution involves a sequential repair process for N-stacked die prior to integration, e.g., pairing of subsequent die. The technique can involve a step-by-step testing process, beginning with the interface between Die1 an Die2. If any defects are detected, they are repaired before moving on to the next phase. Subsequently, the paired die, Die1 and Die2, are tested in conjunction with Die3. If any defects are identified between Die2 and Die3, they are addressed, and the process continues to the next set of pairings for testing and repair. This sequence is repeated until the final die is successfully paired and tested.

Referring to FIGS. 2, 4A and 4B, assume lane 2 fails during testing between Die1 and Die2. As in FIG. 2, the signal S2 is rerouted down via M3 in Die1 to bypass the faulty interconnect between A2t in Die1 and A2r in Die2. On the output side in Die2, the signal is shifted up using M2′ to realign the circuit's original functionality, connecting signal S2 with S2′.

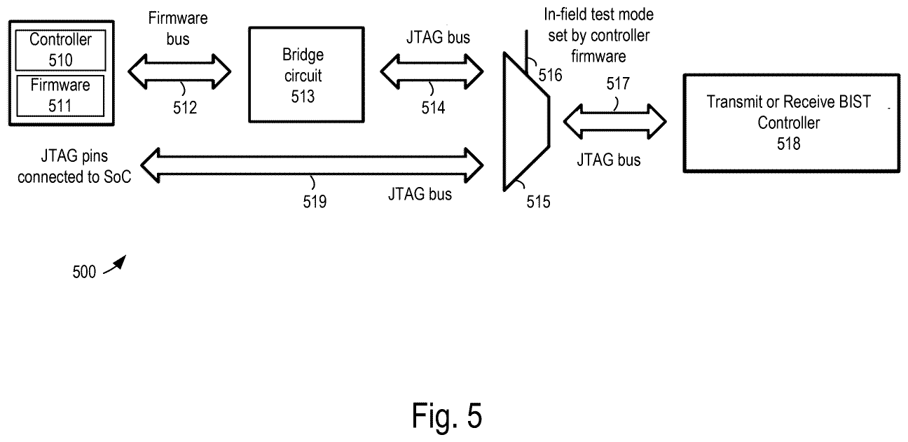

FIG. 5 depicts an in-field repair solution for preemptive die maintenance, in accordance with various embodiments. The system 500 includes a controller 510, e.g., a power management controller (PMC) with firmware 511, which communicates with a bridge circuit 513 via a firmware bus 512. The bridge circuit 513 in turn communicates with a multiplexer 515 via a Joint Test Action Group (JTAG) bus 514. The multiplexer in turn communicates via a JTAG bus 517 with a controller 518. The controller can be an N-dimensional transmit or receive built-in self-test (BIST) controller, such as depicted by the on-die controllers discussed previously.

The multiplexer can route signals from the BIST controller to the JTAG bus 514 and/or a JTAG bus 519. The JTAG bus can be coupled to JTAG pins connected to a system-on-chip (SoC), for example. The multiplexer is controlled by a select line 516 which is based on an in-field test mode set by the controller firmware 511.

As mentioned at the outset, a third solution involves an in-field fault detection and repair technique for N-stacked die. For simplicity, this section illustrates the repair process for a single lane. However, the technique can be expanded to accommodate the repair of two lanes, as well as extending to the repair of an entire bank. A bank is, e.g., as a group of lanes configured in a n×n arrangement of rows and columns, or alternatively, a group of lanes organized in a (n+1)×(n+1) grid.

Each controller can be equipped with an IEEE 1838 JTAG interface for programming a specific set of registers to initiate the test. However, JTAG pins are typically connected to a tester, which is not accessible in the field when the SoC is deployed at a customer site. To address this, a bridge circuit 513 can be used to program the controller via microcontroller or firmware. For example, assume Die1 is a transmit die and Die2 is a receive die as in the following sequence:
Step 1: The microcontroller or controller firmware 511 identifies Die1 and Die2 as being in an idle state.
Step 2: The microcontroller or firmware programs both the Die1 transmit controller and the Die2 receive controller through the bridge circuit using JTAG, setting the number of clock cycles for testing.
Step 3: The microcontroller or firmware initiates a transaction that activates a start bit in the Die1 transmit controller, which then generates test data for the specified number of clock cycles that is programmed in Step 2. This test data traverses through the 3D interconnects and enters Die2. There, if there is any mismatch, the corresponding error bit is set E[i], where i corresponds to the ith lane.
Step 4: After the predetermined clock cycles conclude, both the Die1 transmit controller and the Die2 receive controller signal “test done,” and the Die2 receive controller indicates the test status as pass or fail.
Step 5: The Die2 receive controller shifts out the error chain to record the failing lanes.
Step 6: Depending on whether the test passes or fails, the Die2 receive controller logs in the failing lane numbers in the debug register accordingly. A pass results in the debug register being set to all 1's (the reset value, chosen because 0 is a valid lane number). A failure causes the debug register to reflect the failing lane number (e.g., lane 2).

As mentioned at the outset, and noted in connection with the sensor in FIG. 2, a fourth solution involves a proactive in-field repair technique for preemptive die maintenance predicts potential failures before they occur. Prior to finalizing the design of the silicon chip, a variety of sensors can be strategically placed at key junctions within the vertical die structure to monitor performance and ensure reliability. Among these sensors can be a path margin monitor, which gauges the setup timing margin at the crossing where it is positioned. Additionally, a sensor such as a voltage droop monitor can be used to track any significant voltage reductions.

These sensors can be programmed with predefined threshold values. For instance, if a path margin monitor is placed at a crossing with a setup margin of +10 picoseconds, the threshold might be +5 picoseconds. This means that if, during operation at the customer's site, the setup margin decreases to below +5 picoseconds, the sensor will trigger an interrupt. This alert is sent to the in-field firmware, which then commences a repair procedure. The choice of +5 picoseconds as a threshold is a deliberate safety measure to allow repairs to be initiated proactively before the setup margin falls to 0 picoseconds, at which point an actual failure might occur.

Examples of sensor placement and corresponding threshold values for infield communication triggers are as follows.

### EXAMPLE 1

Location: Between Die1 and Die2, Wire 8
Monitored Parameter before Tape out: Setup timing margin of +10 ps
Threshold of Monitoring parameter during run time: Setup timing margin <+5 ps
Sensor Placed: Timing margin monitor or path margin monitor
In-field Message: Wire 8 between Die1 and Die2 reached the threshold condition and have been repaired.

### EXAMPLE 2

Location: Between Die5 and Die6, Wire 50
Monitored Parameter before Tape out: Voltage droop risk
Threshold of Monitoring parameter during run time: Voltage drop <0.8 V.
Sensor Placed: Voltage Droop Monitor
In-field Message: Wire 50 between Die5 and Die6 reached the threshold condition and have been repaired.

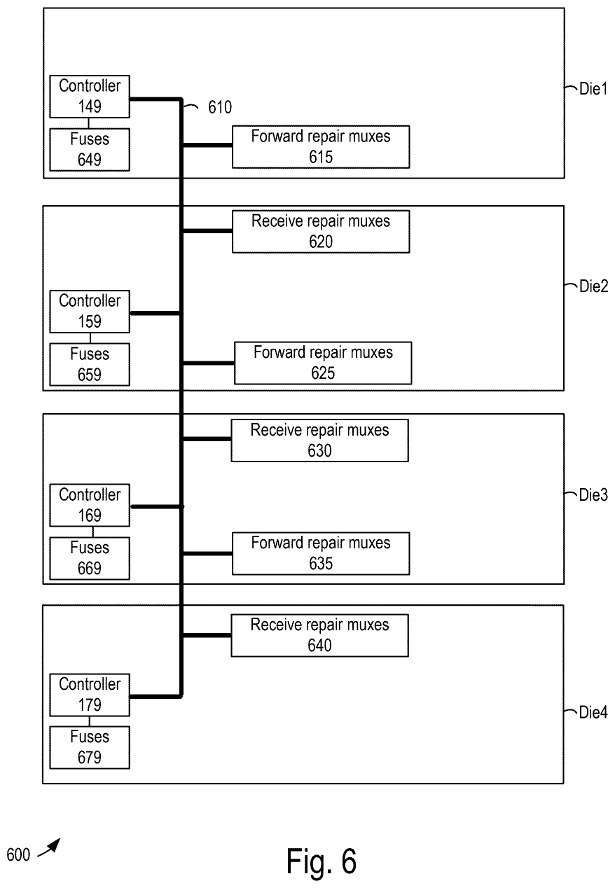

FIG. 6 depicts a stack of die 600 having a multiplexer (mux) select fuse bus 610 coupled to receive and forward repair multiplexers (muxes), in accordance with various embodiments. The repair muxes such as M1, M2 and M3 on the transmit or forwarding side, and M1′, M2′ and M3′ on the receive side, are configured by select signals to re-route faulty signal paths, as discussed, Fuses, as an example of a non-volatile memory, can be provided on each die for use by the respective controllers in identifying the mux settings.

For example, in Die1, the controller 149 can access fuses 649. In Die2, the controller 159 can access fuses 659. In Die3, the controller 169 can access fuses 669. In Die4, the controller 179 can access fuses 679. Additionally, a fuse bus 610 can be coupled to each of the controllers and to the forward and receive repair muxes. For example, the fuse bus 610 can be coupled to forward repair muxes 615 in Die1, receive and forward repair muxes 620 and 625, respectively, in Die2, receive and forward repair muxes 630 and 635, respectively, in Die3, and a receive repair mux 640 in Die4.

The sensors depicted in FIG. 2 can also be coupled to the fuses to obtain thresholds for use in evaluating signals.

As mentioned at the outset, a fifth solution involves a technique to drive select lines of repair multiplexers that provide rerouting of signal paths. As demonstrated above, incorporating repair muxes in each die is useful for executing the most effective repairs or redundancy at every die layer. However, this necessitates configuring the select lines of the repair muxes based on which lane has failed. For instance, in the example provided in FIG. 2, lane 2 exhibits a defect between the transmit die 201 and the receive die 251. To address this, the select line (Sel(M3)) for M3 should be set to route the path 212c to the output of M3. Similarly, in the receive die, the select line for mux M2′ should be adjusted to connect the path 254 to the output on M2′.

The configuration of the mux select lines is contingent upon the identification of failing lane numbers, as shown above. In one approach, the select values are communicated from the receive die to the topmost die in the stack.

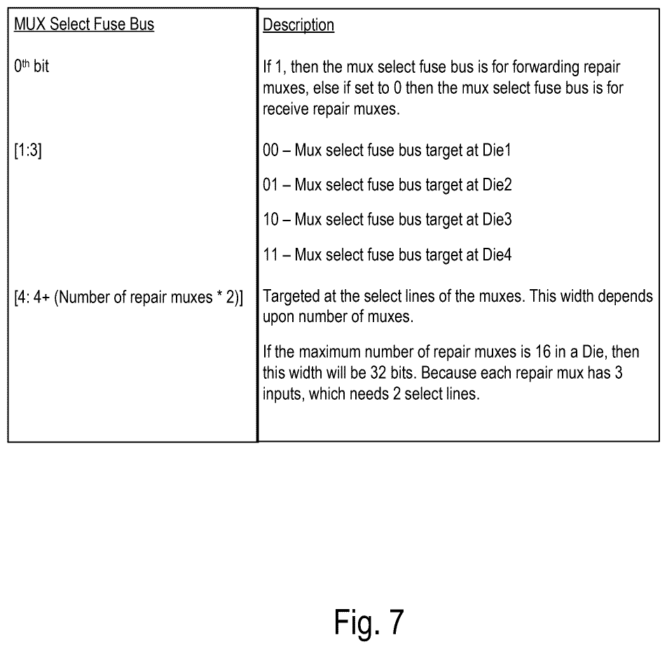

FIG. 7 depicts a table of example descriptions for the multiplexer select fuse bus 610 of FIG. 6, in accordance with various embodiments. For the 0th bit, if it is =1, then the mux select fuse bus is for forwarding repair muxes, else if set to 0 then the mux select fuse bus is for receive repair muxes. For the bits [1:3], 00 indicates a mux select fuse bus target at Die1, 01 indicates a mux select fuse bus target at Die2, 10 indicates a mux select fuse bus target at Die3, and 11 indicates a mux select fuse bus target at Die4. For the bits [4:4+(Number of repair muxes*2)], these are targeted at the select lines of the muxes. The width depends upon number of muxes. For example, if the maximum number of repair muxes is 16 in a die, then this width will be 32 bits, assuming each repair mux has three inputs, requiring two select lines.

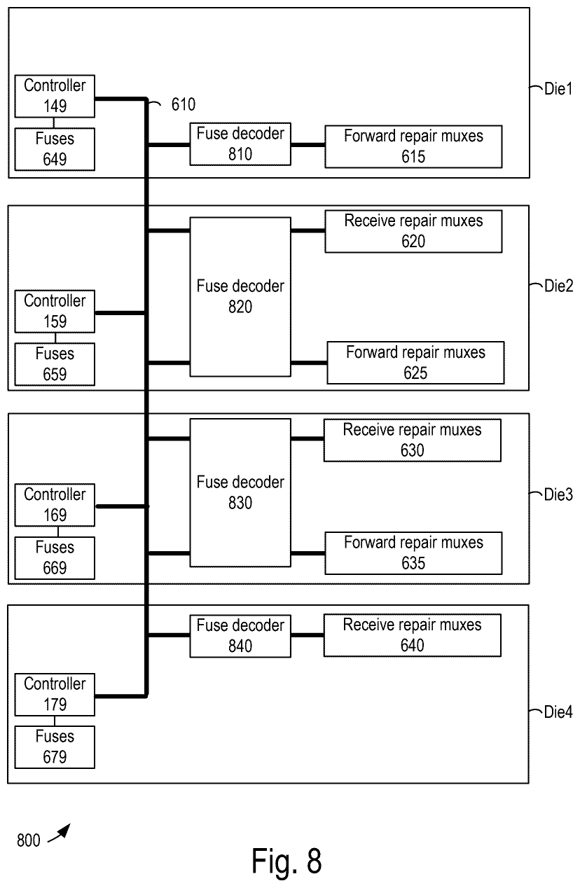

FIG. 8 depicts a stack of die 800 having the multiplexer select fuse bus 610 of FIG. 6 and fuse decoders coupled to receive and forward repair multiplexers, in accordance with various embodiments. The die can include respective controllers, fuses and receive and forward repair muxes as discussed in connection with FIG. 6. Additionally, fuse decoders 810, 820, 830 and 840 are provided in Die1, Die2, Die3 and Die4, respectively. The fuse bus can have a reduce width compared to FIG. 6 due to the use of the fuse decoders.

The number of repair muxes can reach into the hundreds. In the case of server SoCs, for example, there could be 500 repair muxes, requiring 500*2=1000 bits for control. However, routing 1000 bits through all the die is impractical. One solution is to implement a decoder in each chiplet that converts the binary format to one-hot encoding. One-hot encoding provides a codeword where only one bit is set to 1 and the other bits are set to 0. With this approach, the number of bits to route is reduced to log2(1000), which is about 10 bits, to pass through all the die. These 10 bits are then input into each fuse decoder, which translates the 10-bit binary code into 1000 signals using bit blasting. This decoded signal is then used to control the select lines of the repair muxes within each die.

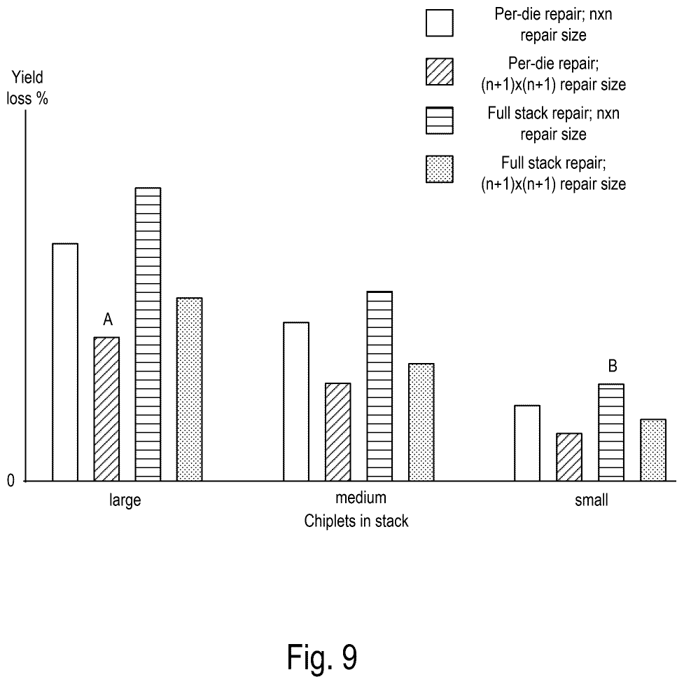

FIG. 9 depicts a bar graph of percentage of yield loss versus a number of chiplets in a stack, analyzed based on the quantity of repair lanes and the repair strategy, in accordance with various embodiments. The graph includes four bars for each of three groups representing a large, medium or small number of chiplets in a stack. In each group, from left to right, the first bar is for the case of a per-layer repair policy with a repair lane size of n×n (lanes configured in a n×n arrangement of rows and columns on the top or bottom surface of a die), the second bar is for the case of a per-layer repair policy with a repair lane size of (n+1)×(n+1), the third bar is for the case of a full stack repair policy with a repair lane size of n×n, and the fourth bar is for the case of a full stack repair policy with a repair lane size of (n+1)×(n+1).

The graph illustrates how yield sensitivity varies with the number of chiplets used, the dimensions of the smallest repairable unit (with larger being preferable), and the chosen redundancy strategy (full stack vs per-layer repair). To mitigate yield loss effectively while keeping design overhead low in terms of both area and power, a redundancy approach can be selected that aligns with the product's specifications in terms of yield and cost.

These decisions should be tailored to the die/chiplet construction, process technology, budget constraints, and desired yield outcomes, ensuring that the repair size is optimized accordingly.

As an example, with chiplets and employing the full stack repair strategy utilizing a n×n repair size (bars with horizontal lines), if the lane repair size is increased to (n+1)×(n+1) (bars with dotted pattern), the yield loss is reduced.

In a similar scenario, with chiplets and employing a per-layer repair strategy with n×n repair lanes (unshaded bars), if the repair lanes are increased to a (n+1)×(n+1) configuration (bars with diagonal lines), the yield loss is reduced.

The yield benefit is therefore a function of the number of chiplets and the size and technique of the repair architecture. A sophisticated per-layer approach with a larger repair size can be an optimal choice (bar “A”) compared to a shorter chiplet stack where a comparable yield can be realized with lesser overhead on power and area on the design (bar “B”).

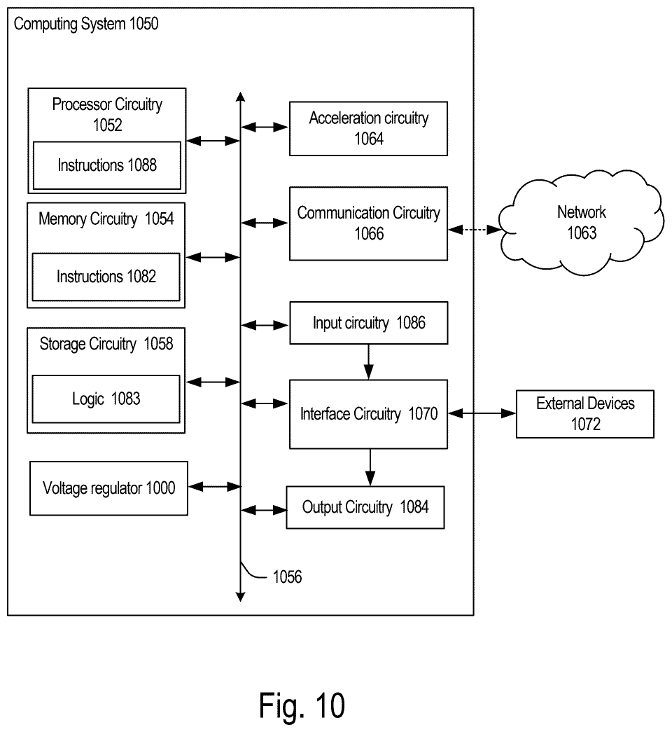

FIG. 10 illustrates an example of components that may be present in a computing system 1050 for implementing the techniques (e.g., operations, processes, methods, and methodologies) described herein.

The computing system 1050 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1050, or as components otherwise incorporated within a chassis of a larger system. In an example implementation, the stacked semiconductor device described herein can be implemented in one or more of the processor circuitry 1052, the memory circuitry 1054, the storage circuitry 1058, and the acceleration circuitry 1064. In one approach, all or part of the computing system 1050 is provided in a SoP, System in Package (SiP) or a System on Chip (SoC).

The voltage regulator can provide a voltage Vout to one or more of the components of the computing system 1050. The memory circuitry 1054 may store instructions, e.g., firmware, and the processor circuitry 1052 may execute the instructions to perform the functions described herein.

The system 1050 includes processor circuitry in the form of one or more processors 1052. The processor circuitry 1052 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1052 may include one or more hardware accelerators (e.g., same or similar to acceleration circuitry 1064), which may be microprocessors, programmable processing devices (e.g., FPGA, ASIC, etc.), or the like. The one or more accelerators may include, for example, computer vision and/or deep learning accelerators. In some implementations, the processor circuitry 1052 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 1052 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1052 may be coupled with or may include memory/storage and may be configured to execute instructions stored in the memory/storage to enable various applications or operating systems to run on the platform 1050. The processors (or cores) 1052 is configured to operate application software to provide a specific service to a user of the platform 1050. In some embodiments, the processor(s) 1052 may be a special-purpose processor(s)/controller(s) configured (or configurable) to operate according to the various embodiments herein.

As examples, the processor(s) 1052 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), M×GPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1052 may be a part of a system on a chip (SoC), System-in-Package (SiP), a multi-chip package (MCP), and/or the like, in which the processor(s) 1052 and other components are formed into a single integrated circuit, or a single package, such as the Edison™ or Galileo™ SoC boards from Intel® Corporation. Other examples of the processor(s) 1052 are mentioned elsewhere in the present disclosure.

The system 1050 may include or be coupled to acceleration circuitry 1064, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1064 may comprise logic blocks or logic fabric and other interconnected resources that may be programmed (configured) to perform various functions, such as the procedures, methods, functions, etc. of the various embodiments discussed herein. In such implementations, the acceleration circuitry 1064 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1052 and/or acceleration circuitry 1064 may include hardware elements specifically tailored for machine learning and/or artificial intelligence (AI) functionality. In these implementations, the processor circuitry 1052 and/or acceleration circuitry 1064 may be, or may include, an AI engine chip that can run many different kinds of AI instruction sets once loaded with the appropriate weightings and training code. Additionally or alternatively, the processor circuitry 1052 and/or acceleration circuitry 1064 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPs™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1052 and/or acceleration circuitry 1064 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin provided by Huawei®, and/or the like. In some hardware-based implementations, individual subsystems of system 1050 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 1050 also includes system memory 1054. Any number of memory devices may be used to provide for a given amount of system memory. As examples, the memory 1054 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 1054 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1054 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1058 provides persistent storage of information such as data, applications, operating systems and so forth. In an example, the storage 1058 may be implemented via a solid-state disk drive (SSDD) and/or high-speed electrically erasable memory (commonly referred to as “flash memory”). Other devices that may be used for the storage 1058 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1054 and/or storage circuitry 1058 may also incorporate three-dimensional (3D) cross-point (XPOINT) memories from Intel® and Micron®.

The memory circuitry 1054 and/or storage circuitry 1058 is/are configured to store computational logic 1083 in the form of software, firmware, microcode, or hardware-level instructions to implement the techniques described herein. The computational logic 1083 may be employed to store working copies and/or permanent copies of programming instructions, or data to create the programming instructions, for the operation of various components of system 1050 (e.g., drivers, libraries, application programming interfaces (APIs), etc.), an operating system of system 1050, one or more applications, and/or for carrying out the embodiments discussed herein. The computational logic 1083 may be stored or loaded into memory circuitry 1054 as instructions 1082, or data to create the instructions 1082, which are then accessed for execution by the processor circuitry 1052 to carry out the functions described herein. The processor circuitry 1052 and/or the acceleration circuitry 1064 accesses the memory circuitry 1054 and/or the storage circuitry 1058 over the interconnect (IX) 1056. The instructions 1082 direct the processor circuitry 1052 to perform a specific sequence or flow of actions, for example, as described with respect to flowchart(s) and block diagram(s) of operations and functionality depicted previously. The various elements may be implemented by assembler instructions supported by processor circuitry 1052 or high-level languages that may be compiled into instructions 1088, or data to create the instructions 1088, to be executed by the processor circuitry 1052. The permanent copy of the programming instructions may be placed into persistent storage devices of storage circuitry 1058 in the factory or in the field through, for example, a distribution medium (not shown), through a communication interface (e.g., from a distribution server (not shown)), over-the-air (OTA), or any combination thereof.

The IX 1056 couples the processor 1052 to communication circuitry 1066 for communications with other devices, such as a remote server (not shown) and the like. The communication circuitry 1066 is a hardware element, or collection of hardware elements, used to communicate over one or more networks 1063 and/or with other devices. In one example, communication circuitry 1066 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1066 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1056 also couples the processor 1052 to interface circuitry 1070 that is used to connect system 1050 with one or more external devices 1072. The external devices 1072 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1050, which are referred to as input circuitry 1086 and output circuitry 1084. The input circuitry 1086 and output circuitry 1084 include one or more user interfaces designed to enable user interaction with the platform 1050 and/or peripheral component interfaces designed to enable peripheral component interaction with the platform 1050. Input circuitry 1086 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1084 may be included to show information or otherwise convey information, such as sensor readings, actuator position(s), or other like information. Data and/or graphics may be displayed on one or more user interface components of the output circuitry 1084. Output circuitry 1084 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1050. The output circuitry 1084 may also include speakers and/or other audio emitting devices, printer(s), and/or the like. Additionally or alternatively, sensor(s) may be used as the input circuitry 1084 (e.g., an image capture device, motion capture device, or the like) and one or more actuators may be used as the output device circuitry 1084 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1050 may communicate over the IX 1056. The IX 1056 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1056 may be a proprietary bus, for example, used in a SoC based system.

The number, capability, and/or capacity of the elements of system 1050 may vary, depending on whether computing system 1050 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1050 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: first, second and third contacts at a first side of a die; first, second and third contacts in respective signal paths with the first, second and third contacts at the first side of the die, at a second side of the die, opposite the first side; a multiplexer having an input side coupled to the first, second and third contacts at the first side of the die, and an output coupled to the second contact at the second side of the die; and a controller coupled to a select line of the multiplexer.

Example 2 includes the apparatus of Example 1, further comprising a logic circuit coupled to the output of the multiplexer and to the controller.

Example 3 includes the apparatus of Example 2, wherein: the input side of the multiplexer is capable of receiving a test signal from the second contact at the first side of the die and to route the test signal to the logic circuit; the logic circuit is capable of receiving a comparison signal from the controller; and the logic circuit is capable of indicating whether the test signal matches the comparison signal.

Example 4 includes the apparatus of any one of Examples 1-3, further comprising a logic circuit coupled to the output of the multiplexer, wherein: the input side of the multiplexer is capable of receiving a test signal from the second contact and to route the test signal to the logic circuit; and the controller is capable of setting the select line of the multiplexer to couple the first or third contact at the first side of the die to the output in place of the second contact at the first side of the die if the logic circuit indicates a fault in the test signal.

Example 5 includes the apparatus of Example 4, wherein: the die is among a plurality of stacked die; and the test signal is receive from another die in the plurality of stacked die.

Example 6 includes the apparatus of any one of Examples 1-5, further comprising a sensor coupled to the second contact, wherein the sensor is capable of receiving a signal from the second contact, perform an evaluation of the signal, and based on the evaluation, provide a pass/fail status regarding the signal to the controller.

Example 7 includes the apparatus of Example 6, wherein the evaluation is of a timing margin of the signal.

Example 8 includes the apparatus of Example 6 or 7, wherein the controller, in response to the pass/fail status being a fail, is capable of setting the select line of the multiplexer to couple the first or third contact at the first side of the die to the output in place of the second contact at the first side of the die.

Example 9 includes the apparatus of any one of Examples 1-8, further comprising: a sensor coupled to the second contact; and fuses to store a plurality of thresholds, wherein the sensor is capable of receiving a signal from the second contact and evaluate the signal relative to one or more of the plurality of thresholds, to provide data for use by the controller.

Example 10 includes the apparatus of any one of Examples 1-9, wherein: the die is among a plurality of stacked die; the first, second and third contacts at the first side of the die are coupled to corresponding contacts of an overlying die of the plurality of stacked die; the first, second and third contacts at the second side of the die are coupled to corresponding contacts of an underlying die of the plurality of stacked die; and the controller is capable of transmitting a message to the overlying die and the underlying die indicating the multiplexer has coupled the first or third contact to the output.

Example 11 includes the apparatus of any one of Examples 1-9, wherein: the die is among a plurality of stacked die; the first, second and third contacts at the first side of the die are coupled to corresponding contacts of an overlying die of the plurality of stacked die; the first, second and third contacts at the second side of the die are coupled to corresponding contacts of an underlying die of the plurality of stacked die; and the controller is capable of receiving a message from the overlying die or the underlying die informing the controller to couple the first or third contact to the output in place of the second contact.

Example 12 includes the apparatus of any one of Examples 1-11, wherein the die is provided in at least one of a System on Chip, a System in Package or a computing device.

Example 13 includes a system, comprising: a memory to store instructions; and a processor to execute the instructions to: receive error data from a circuit on a die indicating that a fault has been detected in a signal path of the die, wherein the signal path is among a plurality of signal paths in the die which extend from contacts at a first side of the die to corresponding contacts at a second, opposing side of the die; in response to the error data, select an alternative signal path for the signal path having the fault; update one or more fuses based on the alternative signal; and control a select line of a multiplexer based on the one or more fuses.

Example 14 includes the system of Example 13, wherein: the memory and processor are on the die among a plurality of stacked die; and the processor is configured to execute the instructions to transmit a message to other die in the plurality of stacked die indicating the alternative signal path is configured to substitute for the signal path having the fault.

Example 15 includes the system of Example 13 or 14, wherein: the circuit comprises a flip-flop coupled to an output of a logic gate; and the logic gate is coupled to the signal path.

Example 16 includes the system of any one of Examples 13-15, wherein the circuit comprises a sensor coupled to the signal path.

Example 17 includes the system of Example 16, wherein the processor is configured to execute the instructions to select a threshold from among a plurality of thresholds for use by the sensor in determining whether the signal has the fault.

Example 18 includes an apparatus, comprising: a contact at a top or bottom side of a die, wherein the contact is in a signal path; a sensor coupled to the signal path; a controller coupled to the sensor, wherein the sensor is configured to perform an evaluation on a signal on the signal path relative to one or more thresholds, and to provide an alert when the evaluation indicates a performance of the signal path deteriorates.

Example 19 includes the apparatus of Example 18, wherein the sensor is configured to perform the evaluation relative to different thresholds at different times in a lifetime of the die.

Example 20 includes the apparatus of Example 18 or 19, wherein the evaluation is of a timing margin of the signal, and a smaller timing margin threshold is used as the die ages.

Example 21 includes a method, comprising: receiving a test signal at an input side of a multiplexer in a die; routing the test signal to a logic circuit; receiving at the logic circuit a comparison signal from a controller; indicating at the logic circuit whether the test signal matches the comparison signal; and setting a select line of the multiplexer based on whether the test signal matches the comparison signal.

Example 22 includes the method of Example 21, wherein the die is among a plurality of stacked die; and the test signal is receive from another die in the plurality of stacked die.

Example 23 includes the method of Example 21 or 22, wherein a first side of the die has first, second and third contacts; a second side of the die, opposite the first side, has first, second and third contacts in respective signal paths with the first, second and third contacts at the first side of the die; the input side of the multiplexer is coupled to the first, second and third contacts at the first side of the die, and an output of the multiplexer is coupled to the second contact at the second side of the die.

Example 24 includes an apparatus, comprising means to perform the method of Example 21 or 22.

Example 25 includes a machine-readable storage including machine-readable instructions which, when executed, cause a computer to implement the method of Example 21 or 22.

Example 26 includes a computer program comprising instructions which, when executed by a computer, cause the computer to carry out the method of Example 21 or 22.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
first, second and third contacts at a first side of a die;
first, second and third contacts in respective signal paths with the first, second and third contacts at the first side of the die, at a second side of the die, opposite the first side;
a multiplexer having an input side coupled to the first, second and third contacts at the first side of the die, and an output coupled to the second contact at the second side of the die; and
a controller coupled to a select line of the multiplexer.

2. The apparatus of claim 1, further comprising a logic circuit coupled to the output of the multiplexer and to the controller.

3. The apparatus of claim 2, wherein:
the input side of the multiplexer is capable of receiving a test signal from the second contact at the first side of the die and to route the test signal to the logic circuit;
the logic circuit is capable of receiving a comparison signal from the controller; and
the logic circuit is capable of indicating indicate whether the test signal matches the comparison signal.

4. The apparatus of claim 1, further comprising a logic circuit coupled to the output of the multiplexer, wherein:
the input side of the multiplexer is capable of receiving a test signal from the second contact and to route the test signal to the logic circuit; and
the controller is capable of setting the select line of the multiplexer to couple the first or third contact at the first side of the die to the output in place of the second contact at the first side of the die if the logic circuit indicates a fault in the test signal.

5. The apparatus of claim 4, wherein:
the die is among a plurality of stacked die; and
the test signal is receive from another die in the plurality of stacked die.

6. The apparatus of claim 1, further comprising a sensor coupled to the second contact, wherein the sensor is capable of receiving a signal from the second contact, perform an evaluation of the signal, and based on the evaluation, provide a pass/fail status regarding the signal to the controller.

7. The apparatus of claim 6, wherein the evaluation is of a timing margin of the signal.

8. The apparatus of claim 6, wherein the controller, in response to the pass/fail status being a fail, is capable of setting the select line of the multiplexer to couple the first or third contact at the first side of the die to the output in place of the second contact at the first side of the die.

9. The apparatus of claim 1, further comprising:
a sensor coupled to the second contact; and
fuses to store a plurality of thresholds, wherein the sensor is capable of receiving a signal from the second contact and evaluate the signal relative to one or more of the plurality of thresholds, to provide data for use by the controller.

10. The apparatus of claim 1, wherein:
the die is among a plurality of stacked die;
the first, second and third contacts at the first side of the die are coupled to corresponding contacts of an overlying die of the plurality of stacked die;
the first, second and third contacts at the second side of the die are coupled to corresponding contacts of an underlying die of the plurality of stacked die; and
the controller is capable of transmitting a message to the overlying die and the underlying die indicating the multiplexer has coupled the first or third contact to the output.

11. The apparatus of claim 1, wherein:
the die is among a plurality of stacked die;
the first, second and third contacts at the first side of the die are coupled to corresponding contacts of an overlying die of the plurality of stacked die;
the first, second and third contacts at the second side of the die are coupled to corresponding contacts of an underlying die of the plurality of stacked die; and
the controller is capable of receiving a message from the overlying die or the underlying die informing the controller to couple the first or third contact to the output in place of the second contact.

12. The apparatus of claim 1, wherein the die is provided in at least one of a System on Chip, a System in Package or a computing device.

13. A system, comprising:
a memory to store instructions; and
a processor to execute the instructions to:
receive error data from a circuit on a die indicating that a fault has been detected in a signal path of the die, wherein the signal path is among a plurality of signal paths in the die which extend from contacts at a first side of the die to corresponding contacts at a second, opposing side of the die;
in response to the error data, select an alternative signal path for the signal path having the fault;
update one or more fuses based on the alternative signal; and
control a select line of a multiplexer based on the one or more fuses.

14. The system of claim 13, wherein:
the memory and processor are on the die among a plurality of stacked die; and
the processor is configured to execute the instructions to transmit a message to other die in the plurality of stacked die indicating the alternative signal path is configured to substitute for the signal path having the fault.

15. The system of claim 13, wherein:
the circuit comprises a flip-flop coupled to an output of a logic gate; and
the logic gate is coupled to the signal path.

16. The system of claim 13, wherein the circuit comprises a sensor coupled to the signal path.

17. The system of claim 16, wherein the processor is configured to execute the instructions to select a threshold from among a plurality of thresholds for use by the sensor in determining whether the signal has the fault.

18. An apparatus, comprising:
a contact at a top or bottom side of a die, wherein the contact is in a signal path;
a sensor coupled to the signal path;
a controller coupled to the sensor, wherein the sensor is configured to perform an evaluation on a signal on the signal path relative to one or more thresholds, and to provide an alert when the evaluation indicates a performance of the signal path deteriorates.

19. The apparatus of claim 18, wherein the sensor is configured to perform the evaluation relative to different thresholds at different times in a lifetime of the die.

20. The apparatus of claim 18, wherein the evaluation is of a timing margin of the signal, and a smaller timing margin threshold is used as the die ages.
